(19) United States
(12) Patent Application Publication
(10) Pub. No.: US 2026/0190921 A1
(43) Pub. Date: Jul. 2, 2026

(54) SUBSTRATE TREATMENT DEVICE AND SUBSTRATE TREATMENT METHOD

(71) Applicant: SCREEN Holdings Co., Ltd., Kyoto (JP)

(72) Inventors: Mitsutoshi SASAKI, Kyoto (JP); Takashi IZUTA, Kyoto (JP)

(21) Appl. No.: 18/865,993

(22) PCT Filed: May 10, 2023
(86) PCT No.: PCT/JP2023/017561

§ 371 Date: Nov. 14, 2024

(30) Foreign Application Priority Data
May 17, 2022 (JP) 2022-080865

(51) Int. Cl. H10P 72/00; H10P 72/30

(52) U.S. Cl. CPC H10P 72/0604; H10P 72/0426; H10P 72/3312

(57) ABSTRACT

A substrate treatment apparatus includes a treatment vessel, a treatment liquid supply, a detector, an acquisition unit, a computer, and a supply controller. The detector detects the concentration of an etching treatment liquid retained in the treatment vessel to acquire a detection concentration. The acquisition unit acquires the exhaustion degree of the etching treatment liquid. The computer computes the concentration of the etching treatment liquid with reference to the exhaustion degree of the etching treatment liquid and exhaustion degree information. The supply controller controls the treatment liquid supply so that the detection concentration acquired by the detector is made equal to the concentration of the etching treatment liquid computed by the computer. The exhaustion degree information indicates a relationship between the concentration of the etching treatment liquid and the exhaustion degree of the etching treatment liquid.

### TECHNICAL FIELD

The present invention relates to a substrate treatment apparatus and a substrate treatment method.

### BACKGROUND ART

Conventionally, apparatuses including a treatment vessel in which a treatment liquid for substrate treatment is retained, and adapted to treat substrates by immersing the substrates in the treatment liquid retained in the treatment vessel are provided as substrate treatment apparatuses. Of these apparatuses, known apparatuses are configured to circulate the treatment liquid from the treatment vessel through a circulation line so that the temperature and the agent concentrations of the treatment liquid are properly maintained while the treatment liquid is caused to flow out of the treatment vessel and back to the treatment vessel (see, for example, PTL 1 and PTL 2).

### Citation List

### Patent Literature

PTL 1: JP 2019-079954 A1
PTL 2: JP 2019-079881 A1

### SUMMARY OF INVENTION

### Problems to be Solved by Invention

Where a plurality of substrates are successively treated in such a substrate treatment apparatus of circulation type, however, the treatment progress degree of substrates being treated in a first lot and the treatment progress degree of substrates being treated in a second lot are often different.

In view of the foregoing, it is an object of the present invention to provide a substrate treatment apparatus and a substrate treatment method that are capable of controlling the progress degree of the substrate treatment.

### Solution to Problems

According to one aspect of the present invention, the substrate treatment apparatus includes a treatment vessel, a treatment liquid supply unit, a detection unit, an acquisition unit, a computation unit, and a supply control unit. In the treatment vessel, an etching treatment liquid containing an organic alkali component is retained, and a substrate is immersed in the etching treatment liquid to be thereby treated. The treatment liquid supply unit supplies the organic alkali component to the treatment vessel. The detection unit detects the concentration of the etching treatment liquid retained in the treatment vessel to acquire a detection concentration. The acquisition unit acquires the exhaustion degree of the etching treatment liquid. The computation unit computes the concentration of the etching treatment liquid with reference to the exhaustion degree of the etching treatment liquid and exhaustion degree information. The supply control unit controls the treatment liquid supply unit so that the detection concentration acquired by the detection unit is made equal to the concentration of the etching treatment liquid computed by the computation unit. The exhaustion degree information indicates a relationship between the concentration of the etching treatment liquid and the exhaustion degree of the etching treatment liquid.

In an inventive aspect, the organic alkali component is tetramethylammonium hydroxide, and the detection unit preferably detects the concentration of tetramethylammonium ions contained in the etching treatment liquid.

In an inventive aspect, the detection unit preferably detects the absorbance of the etching treatment liquid with respect to light of a predetermined wavelength, and the light of the predetermined wavelength is preferably absorbed by the tetramethylammonium ions.

In an inventive aspect, the exhaustion degree preferably indicates the number of substrates treated with the etching treatment liquid, the duration of the treatment of the substrates with the etching treatment liquid, or the type of the substrates treated with the etching treatment liquid.

In an inventive aspect, the substrate treatment apparatus further includes a substrate holding unit that holds a plurality of substrates in a vertically movable manner, and lowers the substrates to immerse the substrates in the etching treatment liquid.

In an inventive aspect, the supply control unit preferably supplies the organic alkali component into the treatment vessel before the substrate holding unit lowers the substrates.

According to another aspect of the present invention, the substrate treatment method is a substrate treatment method to be performed by a substrate treatment apparatus including a treatment vessel in which an etching treatment liquid containing an organic alkali component is retained and a substrate is immersed in the etching treatment liquid to be thereby treated with the etching treatment liquid, and a detection unit that detects the concentration of the etching treatment liquid in the treatment vessel to acquire a detection concentration. The substrate treatment method includes: an acquiring step of acquiring the exhaustion degree of the etching treatment liquid; a computing step of computing the concentration of the etching treatment liquid with reference to the exhaustion degree of the etching treatment liquid and exhaustion degree information; and a controlling step of supplying the organic alkali component into the treatment vessel so that the detection concentration acquired by the detection unit is made equal to the concentration of the etching treatment liquid computed by the computing step, wherein the exhaustion degree information indicates a relationship between the concentration of the etching treatment liquid and the exhaustion degree of the etching treatment liquid.

### Effects of Invention

According to the present invention, the substrate treatment apparatus and the substrate treatment method are provided, which are capable of controlling the progress degree of the substrate treatment.

### BRIEF DESCRIPTION OF DRAWINGS

FIG. 1 Schematic perspective views showing a substrate treatment apparatus according to Example Embodiment 1 of the present invention.

FIG. 2 Schematic sectional view showing the substrate treatment apparatus according to example Embodiment 1.

FIG. 3 Block diagram showing a control device according to Example Embodiment 1.

FIG. 4 Table to be stored in the control device according to Example Embodiment 1.

FIG. 5 Graph showing a relationship between the concentration of an etching treatment liquid LQ and time in the substrate treatment apparatus according to Example Embodiment 1.

FIG. 6 Flowchart showing a substrate treatment method according to Example Embodiment 1.

FIG. 7 Block diagram showing a control device according to Example Embodiment 2 of the present invention.

### DESCRIPTION OF EXAMPLE EMBODIMENTS

Example embodiments of the present invention will hereinafter be described with reference to the attached drawings. In the drawings, like components will be denoted by like reference characters, and duplicate description will be omitted. In the drawings, an X-axis, a Y-axis and a Z-axis are shown as required for easier understanding. The X-axis, the Y-axis and the Z-axis extend orthogonally to each other. The X-axis and the Y-axis are parallel to a horizontal direction, and the Z-axis is parallel to a vertical direction.

### Example Embodiment 1

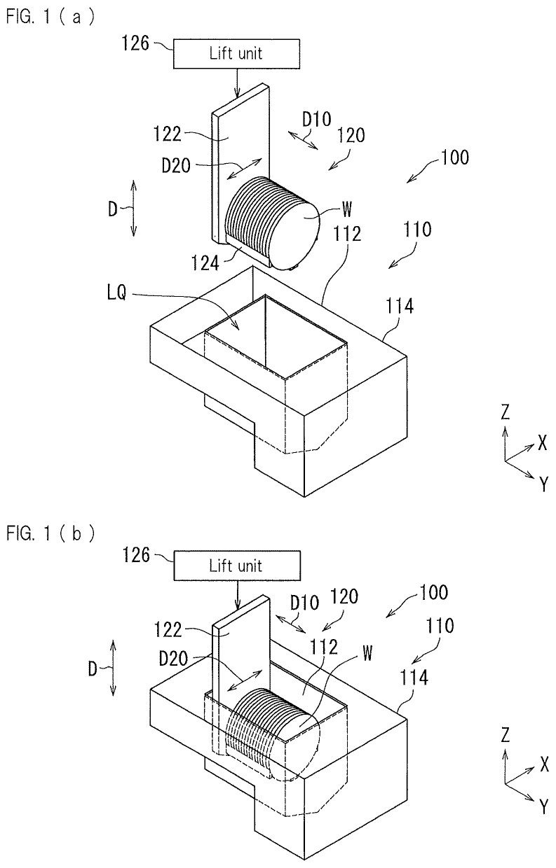

Referring to FIG. 1, a substrate treatment apparatus 100 according to Example Embodiment 1 of the present invention will be described. Referring first to FIG. 1, the substrate treatment apparatus 100 will be described. FIG. 1 is schematic perspective views showing the substrate treatment apparatus 100. Specifically, FIGS. 1(a) and 1(b) are schematic perspective views of the substrate treatment apparatus 100 observed before and after substrates W are loaded into a treatment vessel 110.

As shown in FIGS. 1(a) and 1(b), the substrate treatment apparatus 100 treats the substrates W with an etching treatment liquid LQ in a batch. It is noted that the substrate treatment apparatus 100 may treat each predetermined number of substrates W out of a multiplicity of substrates W with the etching treatment liquid LQ. The predetermined number is an integer not less than 1, e.g., 20.

The substrates W each have a thin plate shape. Typically, the substrates W each have a thin generally-disk shape. Examples of the substrates W include semiconductor wafers, substrates for liquid crystal display devices, substrates for plasma displays, substrates for field emission displays (FED), substrates for optical disks, substrates for magnetic disks, substrates for magneto-optical disks, substrates for photomasks, ceramic substrates, and substrates for solar cells.

An etching treatment is performed to treat the substrates W with the etching treatment liquid LQ. For example, the substrate treatment apparatus 100 performs the etching treatment to etch out silicon oxide films (SiO₂ films) and silicon nitride films (SiN films) from surfaces of the substrates W (silicon substrates) each formed with a pattern. In the etching treatment, either of silicon oxide and silicon nitride is removed from the surfaces of the substrates W.

The etching treatment liquid LQ contains an organic alkali component and water (deionized water). Examples of the organic alkali component include tetramethylammonium hydroxide (TMAH), trimethyl-2-hydroxyethylammonium hydroxide (TMY), ammonium hydroxide and ammonia hydrogen peroxide.

The etching treatment liquid LQ contains, for example, about 0.1% by mass to about 0.5% by mass of tetramethylammonium hydroxide (TMA+OH) and water (H₂O). With the use of the etching treatment liquid LQ, the silicon nitride films (SiN films) are removed from the surfaces of the substrates W. In other words, silicon (Si⁴⁺) dissolves in the etching treatment liquid LQ. As a result, (TMA+Si) is contained in the etching treatment liquid LQ.

The substrate treatment apparatus 100 includes a treatment vessel 110 and a substrate holding unit 120.

The etching treatment liquid LQ is retained in the treatment vessel 110. Specifically, the treatment vessel 110 has a double-vessel structure including an inner vessel 112 and an outer vessel 114. The inner vessel 112 and the outer vessel 114 each have an upper opening that opens upward. The inner vessel 112 is configured so as to be capable of retaining the etching treatment liquid LQ and accommodating the substrates W. The outer vessel 114 is provided around the upper opening of the inner vessel 112 on the outer peripheral surface of the inner vessel 112.

The substrate holding unit 120 holds the substrates W. The substrates W are aligned in tandem in a first direction D10 (Y-direction). In other words, the first direction D10 indicates an alignment direction in which the substrates W are aligned. The first direction D10 is generally parallel to the horizontal direction Further, the substrates W are each generally parallel to a second direction D20. The second direction D20 is generally orthogonal to the first direction D10, and is generally parallel to the horizontal direction.

Specifically, the substrate holding unit 120 includes a lifter. The substrate holding unit 120 is movable vertically upward and downward while holding the substrates W. When the substrate holding unit 120 is moved vertically downward, the substrates W held by the substrate holding unit 120 are immersed in the etching treatment liquid LQ retained in the inner vessel 112.

In FIG. 1(a), the substrate holding unit 120 is located above the inner vessel 112 of the treatment vessel 110. The substrate holding unit 120 is moved vertically downward (lowered in the z direction) while holding the substrates W. Thus, the substrates W are loaded into the treatment vessel 110.

When the substrate holding unit 120 is moved down into the treatment vessel 110, as shown in FIG. 1(b), the substrates W are immersed in the etching treatment liquid LQ within the treatment vessel 110. In Example Embodiment 1, the substrates W, which are aligned in predetermined spaced relation, are immersed in the etching treatment liquid LQ retained in the treatment vessel 110 by the substrate holding unit 120.

Specifically, the substrate holding unit 120 further includes a main body plate 122 and holding rods 124. The main body plate 122 is a plate extending vertically (in the Z-direction). The holding rods 124 extend horizontally (in the Y-direction) from one of opposite major surfaces of the main body plate 122. In the example of FIGS. 1(a) and 1(b), the holding rods 124 include three holding rods 124 extending horizontally from the one major surface of the main body plate 122. The substrates W are aligned in predetermined spaced relation and, in this state, held by the holding rods 124 in upright postures (in vertical postures) with the lower edges of the respective substrates W in abutment against the holding rods 124.

The substrate holding unit 120 may further include a lift unit 126. The lift unit 126 moves the main body plate 122 up and down between a treatment position (a position shown in FIG. 1(b)) in which the substrates W held by the substrate holding unit 120 are located within the inner vessel 112 and a retracted position (a position shown in FIG. 1(a)) in which the substrates W held by the substrate holding unit 120 are located above the inner vessel 112. Therefore, when the main body plate 122 is moved to the treatment position by the lift unit 126, the substrates W held by the holding rods 124 are immersed in the etching treatment liquid LQ.

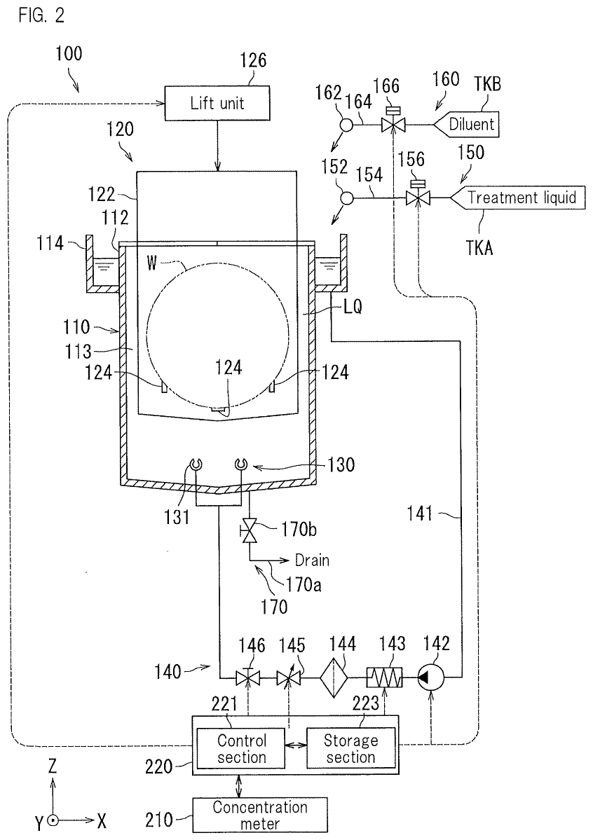

Referring next to FIG. 2, the substrate treatment apparatus 100 will be described in detail. FIG. 2 is a schematic sectional view showing the substrate treatment apparatus 100 according to Example Embodiment 1. As shown in FIG. 2, the substrate treatment apparatus 100 further includes a treatment liquid supply unit 150, a diluent supply unit 160, a concentration meter 210, and a control device 220. The concentration meter 210 is an example of the detection unit.

The treatment liquid supply unit 150 supplies the organic alkali component into the treatment vessel 110. Specifically, the treatment liquid supply unit 150 includes a nozzle 152, a pipe 154 and a valve 156. The nozzle 152 spouts the organic alkali component into the outer vessel 114. The nozzle 152 may supply the organic alkali component into the inner vessel 112.

The nozzle 152 is connected to the pipe 154. An aqueous solution containing high-concentration tetramethylammonium hydroxide (TMA+OH) and water (H₂O) is retained in a treatment liquid supply source TKA. The organic alkali component is supplied to the pipe 154 from the treatment liquid supply source TKA. The pipe 154 is provided with the valve 156. With the valve 156 open, the organic alkali component is spouted from the nozzle 152 to be supplied into the outer vessel 114. Then, the organic alkali component is supplied from the outer vessel 114 into the inner vessel 112.

The diluent supply unit 160 supplies a diluent into the treatment vessel 110. The diluent is, for example, DIW (deionized water). Specifically, the diluent supply unit 160 includes a nozzle 162, a pipe 164 and a valve 166. The nozzle 162 spouts the diluent into the outer vessel 114. The nozzle 162 is connected to the pipe 164. The diluent is supplied to the pipe 164 from a diluent supply source TKB. The pipe 164 is provided with the valve 166. With the valve 166 open, the diluent is spouted from the nozzle 162 to be supplied into the outer vessel 114.

The concentration meter 210 detects the concentration of the etching treatment liquid LQ in the treatment vessel 110 to acquire a detection concentration. More specifically, the concentration meter 210 detects the absorbance of the etching treatment liquid LQ with respect to light of a predetermined wavelength. The light of the predetermined wavelength is absorbed by tetramethylammonium ions (TMA). As a result, the concentration meter 210 detects the concentration of tetramethylammonium ions in the etching treatment liquid LQ to acquire the detection concentration. More specifically, the concentration meter 210 cannot detect the concentration of tetramethylammonium hydroxide (TMA+OH) alone in the etching treatment liquid LQ and, therefore, detects the sum of the concentration of tetramethylammonium hydroxide (TMA+OH) and the concentration of (TMA+Si).

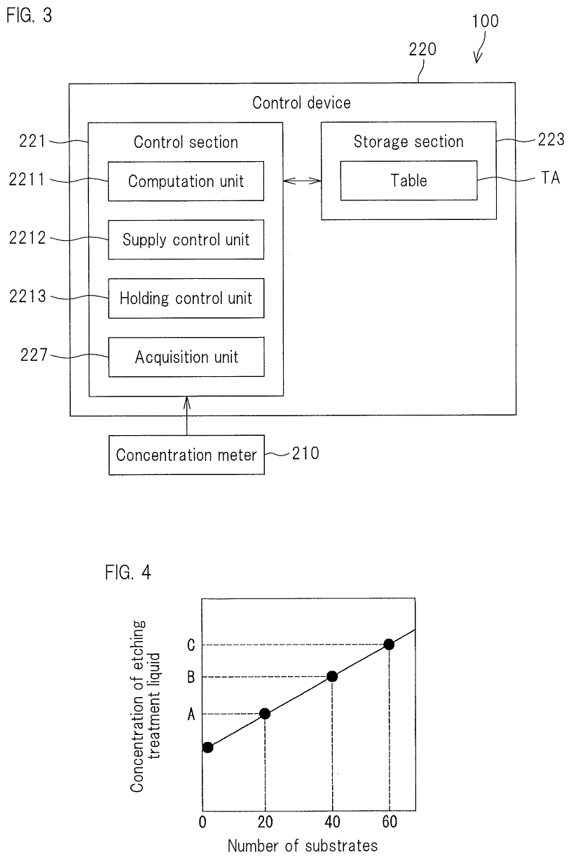

Referring next to FIGS. 3 and 4, the control device 220 will be described. FIG. 3 is a block diagram showing the control device 220 according to Example Embodiment 1. FIG. 4 is a table stored in the control device 220 according to Example Embodiment 1. The table is an example of the exhaustion degree information. As shown in FIG. 3, the control device 220 includes a control section 221 and a storage section 223.

The storage section 223 includes a storage, in which data and a computer program are stored. The processor of the control section 221 executes the computer program stored in the storage of the storage section 223 to control the components of the substrate treatment apparatus 100. The storage section 223 includes, for example, a main storage such as semiconductor memory, and an auxiliary storage such as semiconductor memory and hard disk drive. The storage section 223 may include removable media such as optical disks. The storage section 223 is, for example, a non-temporary computer-readable storage medium. The control device 220 may include an input device and a display device.

The storage section 223 preliminarily stores a table TA. As shown in FIG. 4, the table TA is a graph showing a relationship between the concentration of the etching treatment liquid LQ and the exhaustion degree of the etching treatment liquid LQ. The number of substrates W treated with the etching treatment liquid LQ is plotted as abscissa, and the concentration of the etching treatment liquid LQ is plotted as ordinate. Specifically, the concentration of the etching treatment liquid LQ indicates the concentration of the tetramethylammonium ions (TMA) in the etching treatment liquid LQ.

Silicon (si⁴⁺) dissolves in the etching treatment liquid LQ. As a result, the etching treatment liquid LQ contains (TMA+Si). Therefore, the concentration of tetramethylammonium hydroxide (TMA+OH) is reduced, as the number of the substrates 3 treated with the etching treatment liquid LQ increases. In the table TA shown in FIG. 4, therefore, the tetramethylammonium ion (TMA) concentration of the etching treatment liquid LQ required for the treatment is increased, as the number of the substrates W treated with the etching treatment liquid LQ increases. Specifically, when the number of the substrates W treated with the etching treatment liquid LQ is 20, the tetramethylammonium ion concentration is a concentration A. When the number of the substrates W treated with the etching treatment liquid LQ is 40, the tetramethylammonium ion concentration is a concentration B. When the number of the substrates W treated with the etching treatment liquid LQ is 60, the tetramethylammonium ion concentration is a concentration C.

The control section 221 includes processors such as CPU (Central Processing Unit) and GPU (Graphics Processing Unit).

The control section 221 controls the components of the substrate treatment apparatus 100. For example, the control section 221 includes a computation unit 2211, a supply control unit 2212 and an acquisition unit 227.

The acquisition unit 227 acquires the exhaustion degree of the etching treatment liquid LQ. The exhaustion degree indicates, for example, the number of the substrates W treated with the etching treatment liquid LQ. Specifically, the number of the substrates W of each lot is inputted to the acquisition unit 227, and the acquisition unit 227 counts the number of lots to thereby acquire the number of the substrates W treated with the etching treatment liquid LQ.

The computation unit 2211 computes the concentration of the etching treatment liquid with reference to the exhaustion degree of the etching treatment liquid and the table TA. Specifically, the computation unit 2211 fits the number of the substrates W acquired by the acquisition unit 227 into the table TA to compute the tetramethylammonium ion concentration. Where the number of the substrates W is 20, for example, the computation unit 2211 computes that the tetramethylammonium ion concentration is the concentration A.

The supply control unit 2212 controls the treatment liquid supply unit 150 so that the concentration measured by the concentration meter 210 is made equal to the tetramethylammonium ion (TMA) concentration computed by the computation unit 2211. Specifically, the supply control unit 2212 supplies tetramethylammonium hydroxide to the treatment vessel 110. The concentration meter 210 detects the tetramethylammonium ion concentration of the etching treatment liquid LQ to acquire the detection concentration. If the detection concentration acquired by the concentration meter 210 is lower than the tetramethylammonium ion concentration computed by the computation unit 2211, the supply control unit 2212 supplies tetramethylammonium hydroxide into the treatment vessel 110. When the detection concentration acquired by the concentration meter 210 is made equal to the tetramethylammonium ion concentration computed by the computation unit 2211, on the other hand, the supply control unit 2212 stops supplying tetramethylammonium hydroxide into the treatment vessel 110.

According to Example Embodiment 1, as described with reference to FIGS. 1 to 4, the computation unit 2211 computes the concentration of the etching treatment liquid with reference to the exhaustion degree of the etching treatment liquid and the table TA. The organic alkali component is supplied to the treatment vessel 110 so that the detection concentration acquired by the concentration meter 210 is made equal to the concentration of the etching treatment liquid LQ computed by the computation unit 2211. As a result, it is possible to control the progress degree of the treatment of the substrates W while suppressing the influence of the exhaustion degree of the etching treatment liquid LQ.

According to Example Embodiment 1, the concentration meter 210 detects the tetramethylammonium ion (TMA) concentration of the etching treatment liquid LQ. As a result, it is possible to control the progress degree of the treatment of the substrates W while suppressing the influence of the silicon (Si⁴⁺) content of the etching treatment liquid LQ.

According to Example Embodiment 1, the exhaustion degree indicates the number of the substrates W treated with the etching treatment liquid LQ. As a result, it is possible to control the progress degree of the treatment of the substrates W while suppressing the influence of the number of the substrates W treated with the etching treatment liquid LQ.

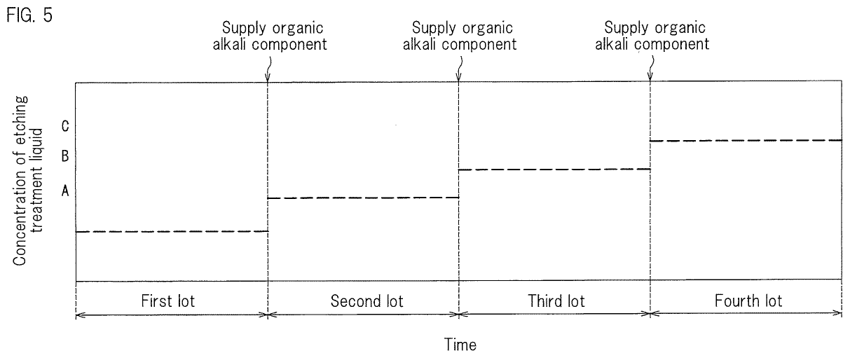

Referring next to FIGS. 3 and 5, the substrate treatment apparatus 100 according to Example Embodiment 1 will be described in greater detail. FIG. 5 is a graph showing a relationship between the concentration of the etching treatment liquid LO and time in the substrate treatment apparatus 100 according to Example Embodiment 1. Time is plotted as abscissa, and the concentration of the etching treatment liquid LQ is plotted as ordinate.

As shown in FIG. 3, the control section 221 further includes a holding control unit 2213. The holding control unit 2213 controls the lift unit 126. As shown in FIG. 5, the holding control unit 2213 treats substrates W successively with the etching treatment liquid LQ. Specifically, the holding control unit 2213 controls the lift unit 126 so as to set twenty substrates W of a first lot in the treatment position, in which the twenty substrates W of the first lot are treated with the etching treatment liquid LQ. Then, the holding control unit 2213 controls the lift unit 126 so as to locate the twenty substrates W of the first lot in the retracted position. Subsequently, the holding control unit 2213 controls the lift unit 126 so as to set twenty substrates W of a second lot in the treatment position, in which the twenty substrates W of the second lot are treated with the etching treatment liquid LQ. Then, the holding control unit 2213 controls the lift unit 126 so as to locate the twenty substrates W of the second lot in the retracted position.

Before the substrate holding unit 120 lowers the substrates W of each of the lots, the supply control unit 2212 supplies tetramethylammonium hydroxide (TMA+OH) into the treatment vessel 110. For example, before the holding control unit 2213 controls the lift unit 126 so as to set the twenty substrates W of the second lot in the treatment position, the Supply control unit 2212 supplies tetramethylammonium hydroxide into the treatment vessel 110. The concentration meter 210 detects the tetramethylammonium ion concentration of the etching treatment liquid LQ to acquire the detection concentration. If the detection concentration acquired by the concentration meter 210 is lower than the tetramethylammonium ion concentration computed by the computation unit 221, the supply control unit 2212 supplies tetramethylammonium hydroxide into the treatment vessel 110. When the detection concentration acquired by the concentration meter 210 is made equal to the tetramethylammonium ion concentration computed by the computation unit 2211, the supply control unit 2212 stops supplying tetramethylammonium hydroxide into the treatment vessel 110. Thereafter, the holding control unit 2213 controls the lift unit 126 so as to set the twenty substrates W of the second lot in the treatment position.

According to Example Embodiment 1, as described with reference to FIGS. 3 and 5, the supply control unit 2212 supplies tetramethylammonium hydroxide (TMA+OH) into the treatment vessel 110 before the substrate holding unit 120 lowers the substrates W. As a result, even where the substrates W are successively treated with the etching treatment liquid LQ, the progress degree of the treatment of the substrates W can be controlled.

Referring next to FIG. 2, the substrate treatment apparatus 100 according to Example Embodiment 1 will be described in greater detail. The substrate treatment apparatus 100 further includes a liquid drain portion 170, a treatment liquid inlet portion 130 and a circulation unit 140.

The liquid drain portion 170 drains the etching treatment liquid LQ from the treatment vessel 110. Specifically, the liquid drain portion 170 includes a liquid drain pipe 170a and a valve 170b. The liquid drain pipe 170a is connected to the bottom wall of the inner vessel 112 of the treatment vessel 110. The liquid drain pipe 170a is provided with the valve 170b. With the valve 170b open, the etching treatment liquid LQ retained in the inner vessel 112 is drained through the liquid drain pipe 170a to the outside. The etching treatment liquid LQ thus drained is fed to a drain liquid treatment system (not shown) and treated. For example, if the tetramethylammonium concentration of the etching treatment liquid LQ retained in the inner vessel 112 is equal to or higher than a predetermined concentration level that is equal to the tetramethylammonium ion concentration of the etching treatment liquid LQ retained in the treatment liquid supply source TKA, the etching treatment liquid LQ retained in the inner vessel 112 is drained to the outside.

When the etching treatment liquid LQ retained in the inner vessel 112 is drained to the outside, the number of substrates W treated with the etching treatment liquid LQ is set to zero by the acquisition unit 227.

The etching treatment liquid LQ is supplied to the treatment vessel 110 through the treatment liquid inlet portion 130. The circulation unit 140 circulates the etching treatment liquid LQ from the treatment vessel 110, and the etching treatment liquid LQ thus circulated is supplied to the treatment liquid inlet portion 130.

Specifically, the treatment liquid inlet portion 130 includes at least one spout 131. The spout 131 is, for example, a nozzle or a pipe. The etching treatment liquid LQ supplied from the circulation unit 140 is spouted from the spout 131.

The circulation unit 140 includes a pipe 141, a pump 142, a heater 143, a filter 144, a regulation valve 145 and a valve 146. The pump 142, the heater 143, the filter 144, the regulation valve 145 and the valve 146 are provided in this order from the upstream side to the downstream side of the pipe 141.

The pipe 141 guides the etching treatment liquid LQ flowing out of the treatment vessel 110 again into the treatment vessel 110. Specifically, the upstream end of the pipe 141 is connected to the outer vessel 114. Therefore, the pipe 141 guides the etching treatment liquid LQ from the outer vessel 114 to the treatment liquid inlet portion 130. The treatment liquid inlet portion 130 is connected to the downstream end of the pipe 141. Specifically, the spout 131 is connected to the downstream end of the pipe 141.

The pump 142 feeds the etching treatment liquid LQ from the pipe 141 to the spout 131. Therefore, the spout 131 spouts the etching treatment liquid LQ supplied from the pipe 141. The filter 144 filters the etching treatment liquid LQ flowing through the pipe 141.

The heater 143 heats the etching treatment liquid LQ flowing through the pipe 141. That is, the heater 143 regulates the temperature of the etching treatment liquid LQ. The regulation valve 145 adjusts the opening degree of the pipe 141 to regulate the flow rate the etching treatment liquid LQ to be supplied to the spout 131. The valve 146 opens and closes the pipe 141.

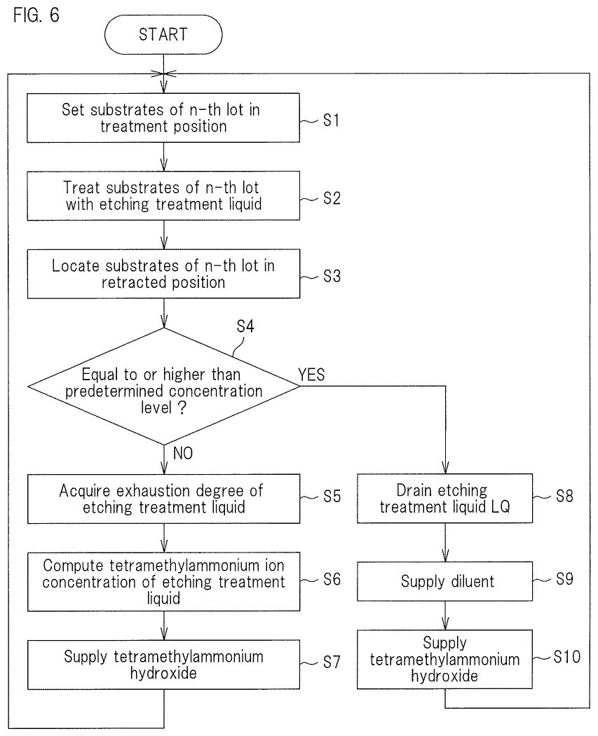

Referring next to FIG. 6, a substrate treatment method according to Example Embodiment 1 will be described. The substrate treatment method is performed by the substrate treatment apparatus 100. FIG. 6 is a flowchart showing the substrate treatment method according to Example Embodiment 1. As shown in FIG. 6, the substrate treatment method includes Steps S1 to S10. Steps S1 to S10 are performed under the control of the control section 221.

First, in Step S1, the holding control unit 2213 controls the lift unit 126 so as to set twenty substrates W of an n-th lot in the treatment position.

Next, in Step S2, the twenty substrates W of the n-th lot are treated with the etching treatment liquid LQ.

Then, in Step S3, the holding control unit 2213 controls the lift unit 126 so as a to locate the twenty substrates W of the n-th lot in the retracted position.

Subsequently, in Step S4, the supply control unit 2212 determines whether or not the detection concentration acquired by the concentration meter 210 is equal to or higher than the predetermined concentration level. If the supply control unit 2212 determines that the detection concentration acquired by the concentration meter 210 is less than the predetermined concentration level in Step S4, the process goes to Step S5.

In Step S5, the acquisition unit 227 acquires the exhaustion degree of the etching treatment liquid LQ. Step S5 corresponds to an example of the acquiring step according to the present invention.

Next, in Step S6, the computation unit 2211 computes the concentration of the etching treatment liquid LQ with reference to the exhaustion degree of the etching treatment liquid LQ and the table TA. Step S6 corresponds to an example of the computing step according to the present invention.

Subsequently, in Step S7, the supply control unit 2212 controls the treatment liquid supply unit 150 so that the detection concentration acquired by the concentration meter 210 is made equal to the tetramethylammonium ion concentration computed by the computation unit 2211. Step S7 corresponds to an example of the controlling step according to the present invention. Then, the process returns to Step S1 for treatment of twenty substrates W of the next lot.

If the supply control unit 2212 determines, in Step S4, that the detection concentration acquired by the concentration meter 210 is equal to or higher than the predetermined concentration level, on the other hand, the process goes to Step S8. In Step S8, the liquid drain portion 170 drains the etching treatment liquid LQ from the treatment vessel 110.

Then, in Step S9, the supply control unit 2212 supplies the diluent into the treatment vessel 110.

Next, in Step S10, the supply control unit 2212 supplies tetramethylammonium hydroxide into the treatment vessel 110 so that the detection concentration acquired by the concentration meter 210 is made equal to the tetramethylammonium ion concentration computed by the computation unit 2211.

According to Example Embodiment 1, as described with reference to FIG. 6, tetramethylammonium hydroxide is supplied into the treatment vessel 110 so that the detection concentration acquired by the concentration meter 210 is made equal to the concentration of the etching treatment liquid LQ computed by the computation unit 2211. As a result, it is possible to control the progress degree of the treatment of the substrates W while suppressing the influence of the exhaustion degree of the etching treatment liquid LQ.

### Example Embodiment 2

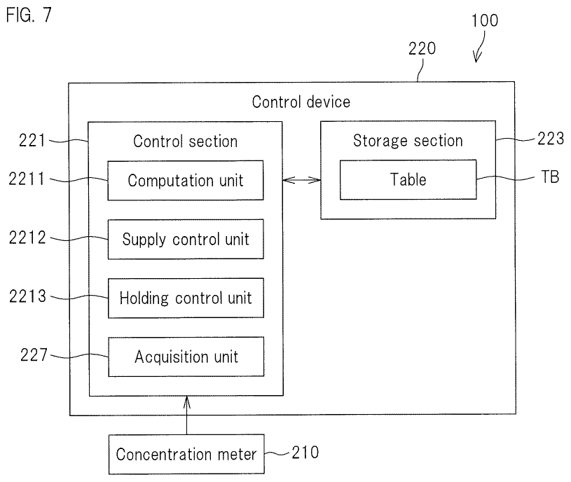

Referring to FIG. 7, a substrate treatment apparatus 200 according to Example Embodiment 2 of the present invention will be described. In Example Embodiment 2, the exhaustion degree includes exhaustion degree information TB indicating the number of the substrates W treated with the etching treatment liquid LQ, the duration of the treatment of the substrates W with the etching treatment liquid LQ, and the type of the substrates W treated with the etching treatment liquid LQ. Mainly in this aspect, Example Embodiment 1 and Example Embodiment 2 are different from each other. Hereinafter, differences between Example Embodiment 2 and Example Embodiment 1 will be mainly described.

The storage section 223 preliminarily stores the exhaustion degree information TB. The exhaustion degree information TB indicates a relationship between the concentration of the etching treatment liquid LQ and the exhaustion degree of the etching treatment liquid LQ. The exhaustion degree includes information about the number of the substrates W treated with the etching treatment liquid LQ, the duration of the treatment of the substrates W with the etching treatment liquid LQ, and the type of the substrates W treated with the etching treatment liquid LQ.

The computation unit 2211 fits the number of the substrates W in the exhaustion degree information TB to compute the concentration of the etching treatment liquid LQ.

The supply control unit 2212 supplies tetramethylammonium hydroxide into the treatment vessel 110 So that the detection concentration acquired by the concentration meter 210 is made equal to the tetramethylammonium ion concentration computed by the computation unit 2211.

According to Example Embodiment 2, as described with reference to FIG. 7, the computation unit 2211 computes the concentration of the etching treatment liquid with reference to the exhaustion degree of the etching treatment liquid and the exhaustion degree information TB. Tetramethylammonium hydroxide is supplied to the treatment vessel 110 so that the detection concentration acquired by the concentration meter 210 is made equal to the concentration of the etching treatment liquid LQ computed by the computation unit 2211. As a result, it is possible to control the progress degree of the treatment of the substrates W while suppressing the influence of the exhaustion degree of the etching treatment liquid LQ.

The example embodiments of the present invention have thus been described with reference to the drawings. However, the present invention is not limited to the example embodiments described above, but various modifications may be made within the scope of the present invention. Further, the components disclosed in the aforementioned example embodiments may be modified as required. For example, some of the components disclosed in one of the example embodiments may be added to the components of the other example embodiment, or some of the components disclosed in one of the example embodiments may be deleted.

In the drawings, the major components are schematically illustrated for easier understanding of the present invention, and are each sometimes illustrated as being different in thickness, length, number, spacing and the like from the reality for convenience of preparation of the drawings. In the example embodiments, the structure of each of the components are shown by way of example but not by way of limitation. It should be understood that various modifications may be made substantially without departing from the effects of the present invention.

### Industrial Applicability

The present invention relates to the substrate treatment apparatus and the substrate treatment method, and thus has industrial applicability.

### DESCRIPTION OF REFERENCE CHARACTERS

100: Substrate treatment apparatus
110: Treatment vessel
120: Substrate holding unit
150: Treatment liquid supply unit
210: Concentration meter (detection unit)
221: Control section
223: Storage section
LQ: Etching treatment liquid

1. A substrate treatment apparatus comprising:
a treatment vessel in which an etching treatment liquid containing an organic alkali component is retained, and a substrate is immersed in the etching treatment liquid to be thereby treated;
a treatment liquid supply that supplies the organic alkali component to the treatment vessel;
a detector that detects a concentration of the etching treatment liquid retained in the treatment vessel to acquire a detection concentration;
an acquisition unit that acquires an exhaustion degree of the etching treatment liquid;
a computer that computes the concentration of the etching treatment liquid with reference to the exhaustion degree of the etching treatment liquid and exhaustion degree information; and
a supply controller that controls the treatment liquid supply so that the detection concentration acquired by the detector is made equal to the concentration of the etching treatment liquid computed by the computer;
wherein the exhaustion degree information indicates a relationship between the concentration of the etching treatment liquid and the exhaustion degree of the etching treatment liquid.

2. The substrate treatment apparatus according to claim 1,
wherein the organic alkali component is tetramethylammonium hydroxide,
wherein the detector detects a concentration of tetramethylammonium ions contained in the etching treatment liquid.

3. The substrate treatment apparatus according to claim 2,
wherein the detector detects an absorbance of the etching treatment liquid with respect to light of a predetermined wavelength,
wherein the light of the predetermined wavelength is absorbed by the tetramethylammonium ions.

4. The substrate treatment apparatus according to claim 1,
wherein the exhaustion degree indicates a number of substrates treated with the etching treatment liquid, a duration of the treatment of the substrates with the etching treatment liquid, or a type of the substrates treated with the etching treatment liquid.

5. The substrate treatment apparatus according to claim 1, further comprising a substrate holder that holds a plurality of substrates in a vertically movable manner, and lowers the substrates to immerse the substrates in the etching treatment liquid.

6. The substrate treatment apparatus according to claim 5, wherein the supply controller supplies the organic alkali component into the treatment vessel before the substrate holder lowers the substrates.

7. A substrate treatment method, which is performed by a substrate treatment apparatus,
the substrate treatment apparatus comprising:
a treatment vessel in which an etching treatment liquid containing an organic alkali component is retained and a substrate is immersed in the etching treatment liquid to be thereby treated with the etching treatment liquid; and
a detector that detects a concentration of the etching treatment liquid in the treatment vessel to acquire a detection concentration,
the substrate treatment method comprising:
an acquiring step of acquiring an exhaustion degree of the etching treatment liquid;
a computing step of computing the concentration of the etching treatment liquid with reference to the exhaustion degree of the etching treatment liquid and exhaustion degree information; and
a controlling step of supplying the organic alkali component into the treatment vessel so that the detection concentration acquired by the detector is made equal to the concentration of the etching treatment liquid computed by the computing step;
wherein the exhaustion degree information indicates a relationship between the concentration of the etching treatment liquid and the exhaustion degree of the etching treatment liquid.

8. The substrate treatment method according to claim 7,
wherein the organic alkali component is tetramethylammonium hydroxide,
wherein the detector detects a concentration of tetramethylammonium ions contained in the etching treatment liquid.

9. The substrate treatment apparatus according to claim 7,
wherein the detector detects an absorbance of the etching treatment liquid with respect to light of a predetermined wavelength,
wherein the light of the predetermined wavelength is absorbed by the tetramethylammonium ions.
